(19) United States
(12) Patent Application Publication
(10) Pub. No.: US 2007/0030866 A1
(43) Pub. Date: Feb. 8, 2007

(54) Semiconductor laser having spot-size converter and method of fabricating the same

(75) Inventors: Young-Hyun Kim, Suwon-si (KR); Yu-Dong Bae, Suwon-si (KR); Young-Churl Bang, Suwon-si (KR)

Correspondence Address: CHA & REITER, LLC, 210 ROUTE 4 EAST STE 103, PARAMUS, NJ, 07652, US

(73) Assignee: Samsung Electronics Co.; LTD

(21) Appl. No.: 11/403,758

(22) Filed: Apr. 13, 2006

(30) Foreign Application Priority Data
Jul. 21, 2005 (KR) 2005-66477

(51) Int. Cl. H01S 3/098; H01S 5/00; H01S 3/04

(52) U.S. Cl. 372/19; 372/46.01; 372/43.01

(57) ABSTRACT

A semiconductor laser having a spot-size converter (SSC) is provided. The semiconductor laser includes: a substrate; a gain region formed on the substrate to emit laser; an SSC region formed on the substrate to convert an optical mode of the emitted laser; and an upper layer formed on the gain region and the SSC region and having a larger thickness in the SSC region in comparison with the gain region. As a result, the laser vertically expands through the upper layer that is thicker along the SSC region so that an NFP (near field pattern) becomes larger and an FFP (far field pattern) becomes smaller, thus minimizing insertion loss into an optical fiber.

### CLAIM OF PRIORITY

This application claims the benefit under 35 U.S.C. §119 of Korean Patent Application No. 10-2005-0066477, filed Jul. 21, 2005, the disclosure of which is incorporated herein in its entirety by reference.

### BACKGROUND OF THE INVENTION

1. Field of the Invention

The present invention relates to a semiconductor laser and a method of fabricating the same, and more particularly to a semiconductor laser having a spot-size converter.

2. Description of Related Art

A light source module is widely used in optical communications. The light source module is fabricated by coupling a semiconductor laser to an optical fiber. Recently, various methods have been developed in order to reduce the cost of manufacturing the light source module. One way is to couple the semiconductor laser to the optical fiber at minimal cost but with no optical loss.

In general, a large insertion loss occurs during a coupling process as an optical mode of the semiconductor laser is quite different from that of the optical fiber. In order to reduce the disagreement between the optical modes, a spot-size converter (SSC) has been proposed to increase the optical mode of the semiconductor laser to that of the optical fiber. Using the SSC, it is possible to directly couple the semiconductor laser and the optical fiber. As a result, the insertion loss may greatly be reduced.

The structure of the semiconductor laser having the SSC must take the following into consideration. First, in order to ensure high-performance of the semiconductor laser, the laser must be securely confined to a waveguide in a gain region since the waveguide has a large optical confinement factor, the optical mode with a small size may face its threshold current decreasing and luminous efficiency increasing. Second, in the SSC region where the optical mode is converted, the optical mode confined in the gain region must be gradually discharged from an output facet such that the size of the optical mode is sufficiently enlarged. Third, the optical mode must be converted in the SSC region without any radiation loss in the laser.

FIG. 1 is a perspective view of a conventional semiconductor laser having an SSC which is disclosed in Korean Patent Publication No. 2000-0019294.

Referring to FIG. 1, a waveguide 18 is formed on a substrate 11, and first and second current blocking layers 12 and 13 are sequentially formed on the substrate 11. The first current blocking layer 12 is made of n-type InP, and the second current blocking layer 13 is made of p-type InP. An n-type electrode 15 is formed on a bottom surface of the substrate 11, and a p-type electrode 16 is formed on a top surface of the waveguide 18. The p-type electrode 16 is formed in the gain region but not in the SSC region. The thickness of the waveguide 18 is uniform in the gain region and gradually tapers down in the SSC region.

The laser is confined in the SSC region in comparison with the gain region, thus the optical mode tend to spread out in the SSC region. A near field pattern (NFP) expands and a far field pattern (FFP), which is a diffraction pattern of the NFP, contracts as the optical mode spreads. Consequently, the laser has a small radiation angle at the output facet for coupling to the optical fiber easier.

However, the above semiconductor laser has drawbacks of large loss in the first current blocking layer 12 and its manufacturing cost is high.

In order to reduce the manufacturing cost, Kitamura discloses a semiconductor laser integrally formed with a waveguide tapered using a selective area growth (SAG) method in the U.S. Pat. No. 5,657,338, entitled “Tapered Thickness Waveguide Integrated Semiconductor Laser”. Although forming the SSC region by reducing the thickness of the waveguide may increase the size of the optical mode in a vertical direction, a growth layer may be subjected to more stress since the composition of the waveguide is different as the thickness of the waveguide is decreased. Hence, if the stress exceeds a certain level, crystal characteristics of the waveguide may be degraded.

Korean Patent Publication No. 2002-77567 discloses a method of increasing the size of an optical mode in a horizontal direction by gradually reducing the width of a waveguide, without reducing the thickness of the waveguide, thereby decreasing manufacturing cost due to a relatively simple manufacturing process.

However, the semiconductor laser having the reduced width of the waveguide in the SSC region has the following problems.

First, the length of the semiconductor laser can be as long as the SSC region so that the current density is lowered to increase the threshold current. Since the SSC region has a multi-quantum well (MQW) structure having the same configuration as an active layer of the gain region, the SSC region and gain region have the same band gap. When current is not sufficiently supplied to the SSC region, the laser transmitted from the gain region is absorbed and thus optical output of the laser is reduced. Therefore, current must be sufficiently supplied to the SSC region so that the laser generated from the MQW structure propagates through the SSC region without loss.

Second, since the SSC region has a small optical confinement factor, the laser has a small gain and thus external quantum efficiency is reduced.

Third, if an upper layer disposed between the waveguide and the p-type electrode is very thick, the laser can sufficiently expand in a vertical direction. But as the distance between the p-type electrode and the waveguide increases, the resistance increases in proportion to the distance. If the resistance increases, the bandwidth is reduced to make it difficult to operate the semiconductor laser at a high speed. In addition, when the upper layer has a large thickness, thermal resistance increases due to trapping of heat generated from the MQW structure, thus its thermal characteristics deteriorate.

### SUMMARY OF THE INVENTION

One aspect of the present invention is to provide a semiconductor laser having a spot-size converter (SSC) wherein the thickness of the upper layer of a SSC region is larger than that of the upper layer of a gain region.

Another aspect of the present invention is to provide a method of fabricating a semiconductor laser having a spot-size converter (SSC) wherein the thickness of the upper layer of a SSC region is larger than that of the upper layer of a gain region.

A semiconductor laser having a spot-size converter (SSC) in accordance with one aspect of the present invention includes a substrate, a gain region formed on the substrate to emit laser, an SSC region formed on the substrate to convert an optical mode of the emitted laser, and an upper layer formed on the gain region and the SSC region and having a thickness on the SSC region larger than that on the gain region.

The semiconductor laser may further include a first electrode formed on a bottom surface of the substrate and a second electrode formed on a top surface of the upper layer. Current may be supplied into the SSC region through the first and second electrode so that the laser may be progressed through the SSC region without loss.

A mask may be formed on the substrate for selective area growth of the upper layer. The mask may be formed on the SSC region. The upper layer is not formed on the mask and the upper layer may have a large thickness in the SSC region.

The mask may have a width of 2˜100 μm depending on desired thickness and width of the upper layer, and the mask may have a length of 10˜20 μm. In addition, at least two masks may be spaced apart from each other by a gap of 5˜100 μm.

A semiconductor laser having a spot-size converter (SSC) in accordance with another aspect of the present invention includes a substrate, a waveguide formed on the substrate to emit laser from a gain region and tapered down toward an output facet from an SSC region to convert an optical mode of the laser, a first upper layer formed on the waveguide of the gain region, and a second upper layer formed on the waveguide of the SSC region and having a thickness larger than that of the first upper layer.

The semiconductor laser may further include a first electrode formed on a bottom surface of the substrate, and a second electrode formed on a top surface of the first upper layer. The second electrode may also be formed on a top surface of the second upper layer.

A current blocking layer may be formed at both sides of the waveguide, and a mask may be formed on the current blocking layer for selective area growth of the second upper layer.

A width of the mask may be larger toward the output facet and may be smaller toward opposite to the output facet.

A semiconductor laser having a spot-size converter (SSC) in accordance with another aspect of the present invention includes a substrate, a waveguide formed on the substrate to emit laser from a gain region and tapered down toward an output facet from an SSC region to convert an optical mode of the laser, a current blocking layer formed at both sides of the waveguide, at least two masks formed on the current blocking layer and spaced apart from each other about the waveguide and an upper layer for burying the waveguide and growing a selected region through the mask to have a thickness on the SSC region larger than that on the gain region.

A method of fabricating a semiconductor laser having a spot-size converter (SSC) in accordance with yet another aspect of the present invention includes preparing a substrate, forming a waveguide on the substrate for emitting laser from a gain region and tapered down toward an output facet from an SSC region to convert an optical mode of the laser, and forming an upper layer for burying the waveguide and having a thickness on the SSC region larger than that on the gain region.

### BRIEF DESCRIPTION OF THE DRAWINGS

FIG. 1 is a perspective view of a conventional semiconductor laser having a spot-size converter.

FIG. 2 is a perspective view of a semiconductor laser having a spot-size converter in accordance with an embodiment of the present invention.

FIGS. 3A to 3C are perspective views illustrating a method of fabricating a semiconductor laser having a spot-size converter in accordance with an embodiment of the present invention.

FIG. 4 is a graph comparing FFPVs of the semiconductor laser in accordance with an embodiment of the present invention and the conventional semiconductor laser.

FIG. 5 is a plan view of masks of a semiconductor laser having a spot-size converter in accordance with another embodiment of the present invention.

FIG. 6 is a plan view of masks of a semiconductor laser having a spot-size converter in accordance with still another embodiment of the present invention.

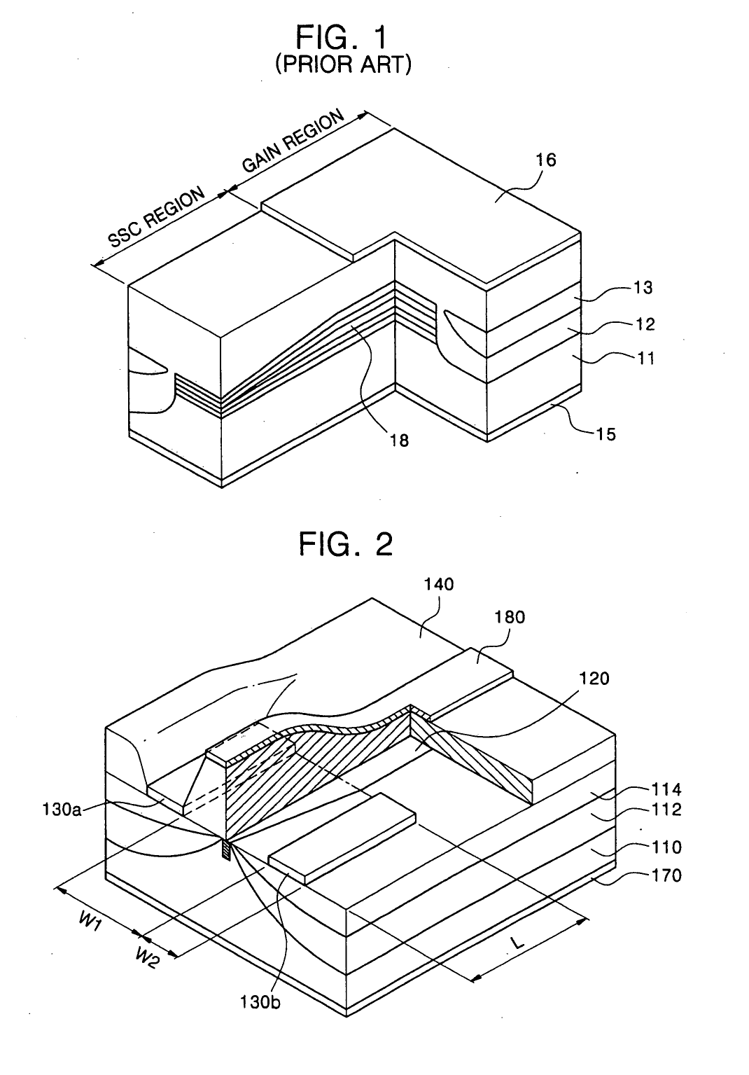

### DETAILED DESCRPTION

In the following detailed description of the exemplary embodiments, reference is made to accompanying drawings which form a part hereof, and in which is shown by way of illustration specific embodiments in which the invention may be practiced. In this regard, directional terminology, such as “top”, “bottom”, “front”, “back”, etc., is used with reference to the orientation of the Figure(s) being described. Because components of embodiments of the present invention can be positioned in a number of different orientations, the directional terminology is used for purposes of illustration and is in no way limiting. It is to be understood that other embodiments may be utilized and structural or logical changes may be made without departing from the scope of the present invention. The following detailed description, therefore, is not to be taken in a limiting sense, and the scope of the present invention is defined by the appended claims.

FIG. 2 is a perspective view of a semiconductor laser having a spot-size converter (SSC) in accordance with an embodiment of the present invention.

Referring to FIG. 2, a waveguide 120 is formed on a substrate 110. The width of the waveguide 120 is uniform at the gain region but is tapered down toward at the output facet of an SSC region. The waveguide 120 has an MQW structure, and the laser is emitted by recombination of carriers. First and second current blocking layers 112 and 114 are formed at both sides of the waveguide 120 to supply current to the MQW structure only. The structure of the waveguide 120 is well known to those skilled in the art, thus it will not be discussed in greater detail herein for the sake of brevity.

Masks 130a and 130b for selective area growth (SAG) are formed at both upper sides of the waveguide 120. The masks 130a and 130b are disposed along a longitudinal direction of the waveguide 120 and symmetrically spaced apart from each other. Note that the masks 130a and 130b shown in FIG. 2 have rectangular shapes, but may have various shapes under the condition that they are spaced apart from each other by a uniform gap.

After forming the masks 130a and 130b, an upper layer 140 is grown by an epitaxial process, such as a metal organic chemical vapor deposition (MOCVD) or molecular beam epitaxy (MBE) method. As a result, the waveguide 120 is buried by the upper layer 140 to form a buried-heterostructure.

Since the masks 130a and 130b have no growth nucleus, the upper layer 140 does not grow. Growth material is spread out to both sides of the masks 130a and 130b and a relatively great deal of growth material is supplied to the both sides of the masks 130a and 130b. Thus, during the same growth time, the thickness of the upper layer 140 at the both sides of the masks 130a and 130b is larger than that of the upper layer 140 in the gain region at which the masks 130a and 130b are not disposed. The upper layer 140 is selectively grown by the masks 130a and 130b so that the upper layer 140 of the gain region and the SSC region have different thickness.

A gap W1 between the masks 130a and 130b may in a range of 5˜100 micrometer (μm) depending on the thickness and width of the upper layer 140. As the gap W1 becomes larger, the upper layer 140 becomes thinner but wider. As gap W1 becomes smaller, the upper layer 140 becomes thicker but narrower.

The length L of the masks 130a and 130b may be equal to or greater than that of the SSC region. But the length L is not greater than that of the SSC region plus 50 μm. If the length L of the masks 130a and 130b is equal to that of the SSC region, only the upper layer 140 formed on the SSC region may have a thickness larger than that of the upper layer 140 formed on the gain region. Otherwise, if the length L of the masks 130a and 130b is slightly greater than that of the SSC region, the upper layer 140 of the gain region adjacent to the SSC region may have a large thickness to make diffusion of the optical mode easier.

The masks 130a and 130b may have a width W2 of 2˜100 μm. As the masks 130a and 130b become wider, the upper layer 140 formed at both sides of the masks 130a and 130b becomes thicker. However, if the masks 130a and 130b become excessively wide, the SAG may be inappropriately performed. Therefore, the width W2 of the masks 130a and 130b should be adjusted depending on the width and thickness of the upper layer 140 based on the SAG A first electrode 170 is formed on a bottom surface 170 of the substrate 110, and a second electrode 180 is formed on the upper layer 140. The first electrode 170 may be an n-type electrode, and the second electrode 180 may be a p-type electrode.

In one embodiment, the second electrode 180 is formed only on the gain region. In another embodiment, the second electrode 180 may be formed on the SSC region in addition to the gain region. In this case, since the current can be supplied to the SSC region, the laser can propagate through the waveguide 120 on the SSC region without loss.

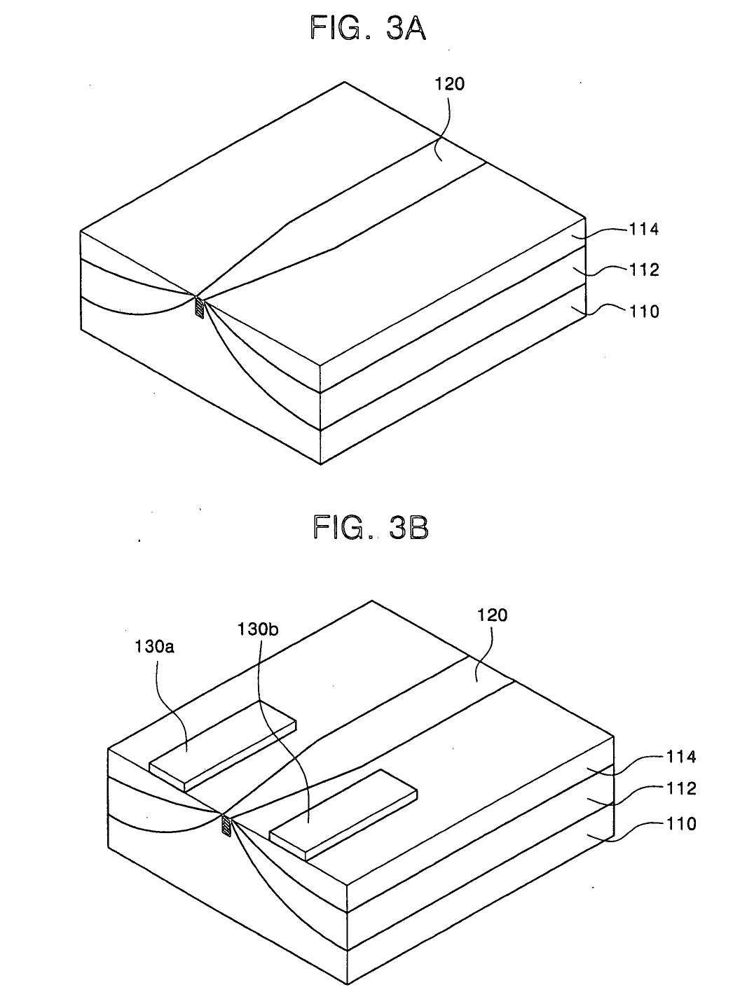

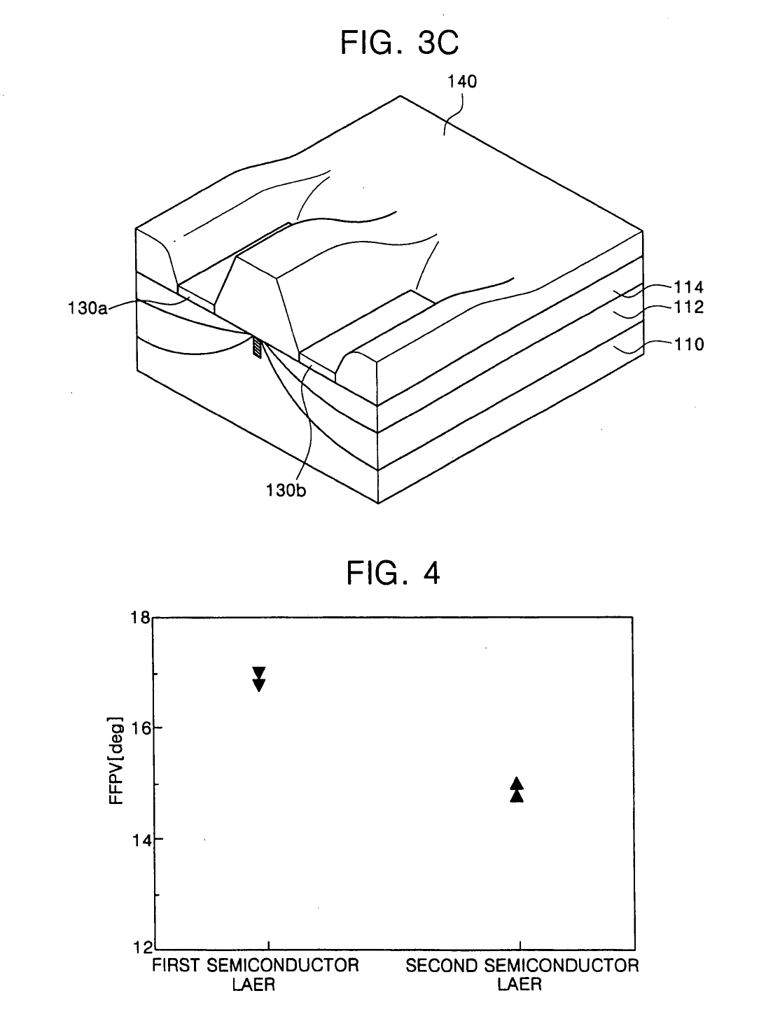

FIGS. 3A to 3C are perspective views illustrating a method of fabricating a semiconductor laser having a spot-size converter in accordance with an embodiment of the present invention.

Referring to FIG. 3A, after forming an MQW structure on a substrate 110, a waveguide 120 is formed by a lithographic method. The width of the waveguide 120 is uniform in the gain region and gradually reduced in the SSC region. After forming the waveguide 120, first and second current blocking layers 112 and 114 are formed at both sides of the waveguide 120 using an MOCVD method, and so on.

Referring to FIG. 3B, a dielectric layer (not shown) is formed of SiO₂ or SiₓNₓ on the second current blocking layer 114. The dielectric layer is deposited by a thermal CVD method, and so on. Then, the masks 130a and 130b are formed at both sides about the tapered waveguide 120 of the SSC region using a lithographic method.

Referring to FIG. 3C, an upper layer 140 is grown by an epitaxial method, such as an MOCVD method or other similar processes known by artisian. In this case, since the upper layer 140 is not formed on the masks 130a and 130b, the upper layer 140 formed on the tapered waveguide 120 has a relatively large thickness. The waveguide 120 is buried by the upper layer 140.

After finishing the growth of the upper layer 140, a first electrode 170 is formed on a bottom surface of the substrate 110, and a second electrode 180 is formed on the upper layer 140.

Now, operations of the semiconductor laser having an SSC will be described hereinafter.

When a current is supplied to the first and second electrodes 170 and 180, the laser is emitted by recombination of carriers in an MQW structure on the gain region. The upper layer 140 of the gain region has a thickness relatively larger than that of the upper layer 140 of the SSC region. Since a distance between the second electrode and the waveguide is small enough, the resistance on the gain region is reduced. Also, as a ratio of the current applied to the gain region when the current supplied to the semiconductor laser increases in comparison with a ratio of the current supplied to the SSC region having relatively high resistance due to the large thickness of the upper layer 140, the threshold current is lowered, bandwidth is widened, and thermal characteristics are improved.

Since the upper layer 140 formed on the SSC region has a thickness larger than that of the upper layer 140 formed on the gain region, the resistance on the SSC region increases. The laser sufficiently expands in a vertical direction through the thickened upper layer 140 along the SSC region. Therefore, a near field pattern (NFP) becomes larger and a far field pattern (FFP) becomes smaller. The coupling loss to the optical fiber can be minimized. In addition, as the laser vertically expands, the optical mode at the output facet has an approximate circular shape. A misalignment between the optical fiber and the optical mode is reduced, thereby additionally reducing loss due to mode misalignment.

According to the present invention, the upper layer 140 in the SSC region has a thickness different from the upper layer 140 in the gain region through the SAG to maintain the low resistance in the gain region and to sufficiently expand the optical mode in the SSC region.

FIG. 4 is a graph comparing FFP in a vertical direction (FFPV) of the semiconductor laser in accordance with an embodiment of the present invention and the conventional semiconductor laser.

A first semiconductor laser has a uniform thickness in a gain region and an SSC region. An upper layer of the first semiconductor laser is formed without a mask. A second semiconductor laser in accordance with an embodiment of the present invention has a thickness different from each other in the gain region and the SSC region. An upper layer of the second semiconductor laser is formed through SAG after masks are formed at both sides of a tapered waveguide to have a gap W1 of 20 μm therebetween and a width W2 of 20 μm.

Referring to FIG. 4, the selectively grown second semiconductor laser has an FFPV smaller than that of the first semiconductor laser by about two degrees. The second semiconductor laser has a thick upper layer in the SSC region to vertically expand the optical mode, so that the NFP becomes larger and the FFP becomes smaller.

Table 1 is a table comparing characteristics of current versus optical efficiency of the first and second semiconductor lasers.

TABLE 1

| | Ith[mA] | SE1[mW/mA] | SE2[mW/mA] | Lin1[%] | Lin2[%] |
|---|---|---|---|---|---|
| First | 9.38 | 0.394 | 0.378 | 96.0 | 91.5 |
| semi- | | | | | |
| conductor | | | | | |
| laser | | | | | |
| Second | 8.25 | 0.414 | 0.402 | 97.2 | 95.6 |
| semi- | | | | | |
| conductor | | | | | |
| laser | | | | | |

Referring to Table 1, the second semiconductor laser has a threshold current Ith smaller than that of the first semiconductor laser. The laser can be emitted at the threshold current smaller than that of the first semiconductor laser, so that the current efficiency of the second semiconductor laser is improved.

A slope efficiency SE1 is measured at the current 5 mili-ampere (mA), and a slope efficiency SE2 is measured at the current 10 mA. The second semiconductor laser has a slope efficiency SE1, SE2 larger than that of the first semiconductor laser. Linearity Lin1 of the optical efficiency is measured between the threshold current Ith and the current 5 mA, and Linearity Lin2 of the optical efficiency is measured between the current 5 mA and current 10 mA. The second semiconductor laser also has the linearity Lin1, Lin2 larger than that of the first semiconductor laser. That is, the second semiconductor laser in accordance with an embodiment of the present invention has good current-optical efficiency characteristics in comparison with the conventional first semiconductor laser.

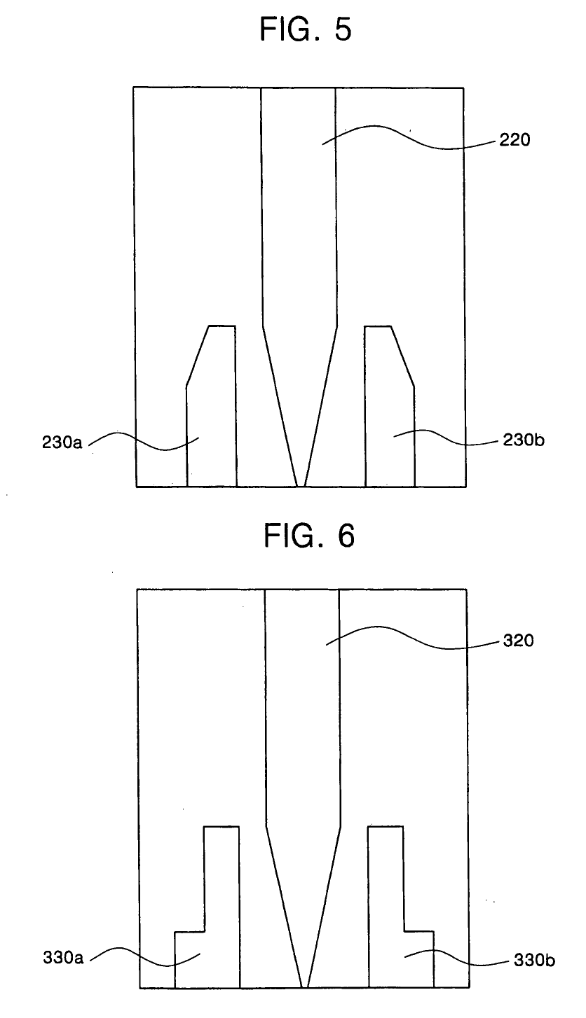

FIG. 5 is a plan view of masks of a semiconductor laser having a spot-size converter in accordance with another embodiment of the present invention.

Referring to FIG. 5, masks 230a and 230b are formed to have a reduced width at a boundary of a gain region and an SSC region. As the width of the masks 230a and 230b becomes smaller, an upper layer grown on a waveguide 220 becomes thinner. Therefore, it is possible to prevent unexpected high variations of thickness in the upper layer at the boundary of the gain region and the SSC region.

FIG. 6 is a plan view of masks of a semiconductor laser having a spot-size converter in accordance with yet another embodiment of the present invention.

Referring to FIG. 6, the width of masks 330a and 330b becomes larger in the direction of an output facet, i.e., a open end of an SSC region. As the width of the masks 330a and 330b becomes larger, an upper layer becomes thicker. Therefore, it is possible to expand an optical mode at the output facet.

Note that the embodiment in accordance with the present invention describes the semiconductor laser with an SSC, it is possible to apply the invention to various semiconductor optical devices having a waveguide structure such as a semiconductor optical amplifier (SOA), a modulator, a photo detector, a wavelength converter, and so on.

As can be seen from the foregoing, the laser can vertically expand through the upper layer having a thickness increased along the SSC region so that the NFP becomes larger and the FFP becomes smaller to minimize insertion loss to the optical fiber. In addition, it is possible to reduce the threshold current of the semiconductor laser and improve current-optical efficiency characteristics by maintaining low resistance in the gain region.

While this invention has been described in connection with what is presently considered to be the most practical and preferred embodiment, it is to be understood that the invention is not limited to the disclosed embodiment, but on the contrary, it is intended to cover various modifications within the spirit and the scope of the invention, which is set forth in the appended claims.

What is claimed is:

1. A semiconductor laser having a spot-size converter (SSC), comprising:
a substrate;
a gain region formed on the substrate to emit a laser;
an SSC region formed on the substrate to convert an optical mode of the emitted laser; and
an upper layer formed on the gain region and the SSC region, the upper layer having a thickness on the SSC region larger than that on the gain region.

2. The semiconductor laser according to claim 1, further comprising a first electrode formed on a bottom surface of the substrate and a second electrode formed on a top surface of the upper layer.

3. The semiconductor laser according to claim 1, further comprising a mask formed on the substrate for providing a selective area growth of the upper layer.

4. The semiconductor laser according to claim 3, wherein the mask is formed in the SSC region.

5. The semiconductor laser according to claim 3, wherein the upper layer is not formed on the mask.

6. The semiconductor laser according to claim 3, wherein the mask has a width of 2 to 100 μm.

7. The semiconductor laser according to claim 3, wherein the mask has a length of 10 to 20 μm.

8. The semiconductor laser according to claim 3, wherein at least two masks are spaced apart from each other by a predetermined distance.

9. The semiconductor laser according to claim 8, wherein the masks have a gap of 5 to 100 μm therebetween.

10. A semiconductor laser having a spot-size converter (SSC), comprising:
a substrate;
a waveguide formed on the substrate to emit a laser in a gain region and tapered downwardly toward an output facet in an SSC region to convert an optical mode of the laser;
a first upper layer formed on the waveguide in the gain region; and
a second upper layer formed on the waveguide in the SSC region, the second upper layer having a thickness larger than that of the first upper layer.

11. The semiconductor laser according to claim 10, further comprising a first electrode formed on a bottom surface of the substrate, and a second electrode formed on a top surface of the first upper layer.

12. The semiconductor laser according to claim 11, wherein the second electrode is formed on the first and second upper layers.

13. The semiconductor laser according to claim 10, further comprising a current blocking layer formed at both sides of the waveguide.

14. The semiconductor laser according to claim 13, further comprising a mask formed on the current blocking layer for providing a selective area growth of the second upper layer.

15. The semiconductor laser according to claim 14, wherein the mask has a width that is larger toward the output facet.

16. The semiconductor laser according to claim 14, wherein the mask has a width that is smaller toward an opposite side of the output facet.

17. The semiconductor laser according to claim 14, wherein at least two masks are spaced apart from each other.

18. The semiconductor laser according to claim 17, wherein the masks are symmetrically formed about the waveguide.

19. A semiconductor laser having a spot-size converter (SSC), comprising:
a substrate;
a waveguide formed on the substrate to emit a laser in a gain region and tapered down toward an output facet in an SSC region to convert an optical mode of the laser;
a current blocking layer formed at both sides of the waveguide;
at least two masks formed on the current blocking layer and spaced apart from each other about the waveguide; and
an upper layer for burying the waveguide, the upper layer being selectively grown by the mask to have a thickness in the SSC region larger than that in the gain region.

20. The semiconductor laser according to claim 19, further comprising a first electrode formed on a bottom surface of the substrate and a second electrode formed on a top surface of the upper layer.

21. The semiconductor laser according to claim 19, wherein the mask is formed in the SSC region.

22. A method of fabricating a semiconductor laser having a spot-size converter (SSC), comprising:
preparing a substrate;
forming a waveguide on the substrate, the waveguide which emits a laser in a gain region and is tapered down toward an output facet in an SSC region to convert an optical mode of the laser; and
forming an upper layer which buries the waveguide and has a thickness in the SSC region larger than that in a gain region.

23. The method according to claim 22, further comprising:
forming a first electrode on a bottom surface of the substrate; and
forming a second electrode on the upper layer.

24. The method according to claim 22, further comprising:
after forming the waveguide, forming a current blocking layer at both sides of the waveguide.

25. The method according to claim 24, further comprising:
forming a mask on the current blocking layer for selective area growth of the upper layer.

26. The method according to claim 25, wherein at least two masks are spaced apart from each other about the waveguide.
